(19) United States
(12) Patent Application Publication
(10) Pub. No.: US 2012/0074565 A1
(43) Pub. Date: Mar. 29, 2012

(54) SEMICONDUCTOR DEVICE PROVIDED WITH REAR PROTECTIVE FILM ON OTHER SIDE OF SEMICONDUCTOR SUBSTRATE AND MANUFACTURING METHOD OF THE SAME

(75) Inventor: Taisuke KOROKU, Sagamihara-shi (JP)

(73) Assignee: CASIO COMPUTER CO., LTD., Tokyo (JP)

(21) Appl. No.: 13/232,180

(22) Filed: Sep. 14, 2011

(30) Foreign Application Priority Data
Sep. 24, 2010 (JP) 2010-213390

(51) Int. Cl. H01L 21/78; H01L 23/485

(52) U.S. Cl. 257/737; 438/462; 257/E23.021; 257/E21.599

(57) ABSTRACT

An opening is formed in a part of a rear protective film corresponding to the center of a dicing street by laser processing which applies a laser beam. The rear protective film is formed on the lower surface of a semiconductor wafer, and made of a resin. By using a resin cutting blade, parts of a sealing film and the upper side of the semiconductor wafer corresponding to the dicing street and both its sides are then cut to form a trench. By using a silicon cutting blade, parts of the semiconductor wafer and the rear protective film corresponding to the dicing street are then cut. In this case, cutting of the rear protective film with the silicon cutting blade is reduced by the opening.

### CROSS-REFERENCE TO RELATED APPLICATIONS

This application is based upon and claims the benefit of priority from prior Japanese Patent Application No. 2010-213390, filed Sep. 24, 2010, the entire contents of which are incorporated herein by reference.

### BACKGROUND OF THE INVENTION

1. Field of the Invention

The present invention relates to a semiconductor device provided with a rear protective film on the other side of a semiconductor substrate and a manufacturing method of the same.

2. Description of the Related Art

What is called a chip size package (CSP) is known from Jpn. Pat. Appln. KOKAI Publication No. 2006-229112. This semiconductor device comprises a semiconductor substrate. A wiring line is provided on the upper surface of an insulating film which is provided on the semiconductor substrate. A columnar external connection electrode is provided on the upper surface of a land of the wiring line. A sealing film made of a resin is provided on the upper surface of the insulating film including the wiring line around the external connection electrode. A solder bump is provided on the upper surface of the external connection electrode. A rear protective film made of a resin is provided on the lower surface of the semiconductor substrate.

According to Jpn. Pat. Appln. KOKAI Publication No. 2006-229112, an insulating film, a wiring line, an external connection electrode, and a sealing film are first formed on a semiconductor substrate in a wafer state (hereinafter referred to as a semiconductor wafer). The lower side of the semiconductor wafer is then ground to reduce the thickness of the semiconductor wafer. A rear protective film is then formed on the lower surface of the semiconductor wafer. A solder bump is then formed on the upper surface of the external connection electrode. The sealing film, the semiconductor wafer, and the rear protective film are then cut along dicing streets, thereby obtaining semiconductor devices.

Although not described in Jpn. Pat. Appln. KOKAI Publication No. 2006-229112, a blade used for the dicing comprises a grindstone produced by molding a binder containing abrasive grains (e.g., diamond grains) into a disk. Depending on processing conditions, the concentration of the abrasive grains needs to be selected. That is, depending on the concentration of the abrasive grains, load applied to each abrasive grain during cutting changes, and the likelihood of self-sharpening (appearance of new abrasive grains in response to the abrasion of the binder caused by cutting) changes. Thus, extra force is applied to some cutting targets, and the cut surfaces of such cutting targets are easily chipped.

Therefore, it is not preferable to cut the resin sealing film, the semiconductor wafer, and the resin rear protective film with one kind of blade. Accordingly, the resin sealing film and the upper side of the semiconductor wafer may be cut with a resin cutting blade, while the rest of the semiconductor wafer and the resin rear protective film may be cut with a semiconductor cutting blade lower in the concentration of abrasive grains than the resin cutting blade. This inhibits the chipping of the cut surface of the semiconductor wafer.

However, if the resin rear protective film is cut with the semiconductor cutting blade, this blade is gradually clogged with the resin. If the semiconductor wafer is cut with the blade being clogged with the resin, the cut surface of the semiconductor wafer is chipped. To avoid such a situation, test cutting called precutting that uses a precut substrate (a dummy of an object to be processed) is needed to stabilize the cutting performance of the blade. However, the problem is that frequent precutting with the blade shortens the life of the blade.

It is therefore an object of the present invention to inhibit the chipping of the cut surface of a semiconductor wafer, slow the clogging of a semiconductor cutting blade with a resin, and reduce the frequency of precutting, thereby prolonging the life of the semiconductor cutting blade. Alternatively, it is an object of the present invention to provide a semiconductor device manufacturing method capable of cutting a semiconductor wafer without using a semiconductor cutting blade, and a semiconductor device thereby obtained.

### BRIEF SUMMARY OF THE INVENTION

According to one aspect of the present invention, there is provided a semiconductor device comprising: a semiconductor substrate; a sealing film provided on one side of the semiconductor substrate; and a rear protective film provided on the other side of the semiconductor substrate except for at least its outer edge.

According to another aspect of the present invention, there is provided a semiconductor device manufacturing method comprising: forming a sealing film on one side of a semiconductor wafer and forming a rear protective film on the other side thereof; forming an opening in a part of the rear protective film corresponding to a dicing street; forming, with a first blade, a trench in at least a part of the sealing film corresponding to the dicing street; and dicing, with a second blade, at least the semiconductor wafer in a part corresponding to the dicing street.

According to another aspect of the present invention, there is provided a semiconductor device manufacturing method comprising: forming a sealing film on one side of a semiconductor wafer and forming a rear protective film on the other side thereof; forming an opening in a part of the rear protective film corresponding to a dicing street; forming, with a first blade, a trench in at least a part of the sealing film corresponding to the dicing street; and dividing, by stealth dicing, at least the semiconductor wafer in a part corresponding to the dicing street.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a plan view of a semiconductor device according to a first embodiment of the present invention;

FIG. 2 is a sectional view of a part substantially taken along line II-II of FIG. 1;

FIG. 3 is a sectional view of an initially prepared assembly in one example of a method of manufacturing the semiconductor device shown in FIG. 1 and FIG. 2;

FIG. 4 is a sectional view of a step following FIG. 3;

FIG. 5 is a sectional view of a step following FIG. 4;

FIG. 6 is a sectional view of a step following FIG. 5;

FIG. 7 is a sectional view of a step following FIG. 6;

FIG. 8 is a sectional view of a step following FIG. 7;

FIG. 9 is a sectional view of a step following FIG. 8;

FIG. 10A is a plan view of the assembly shown in FIG. 9;

FIG. 10B is a sectional view substantially taken along line B-B of FIG. 10A;

FIG. 10C is a diagram showing the assembly shown in FIG. 10B that is disposed on a chuck table;

FIG. 11 is a sectional view of a step following FIG. 9;

FIG. 12 is a sectional view of a step following

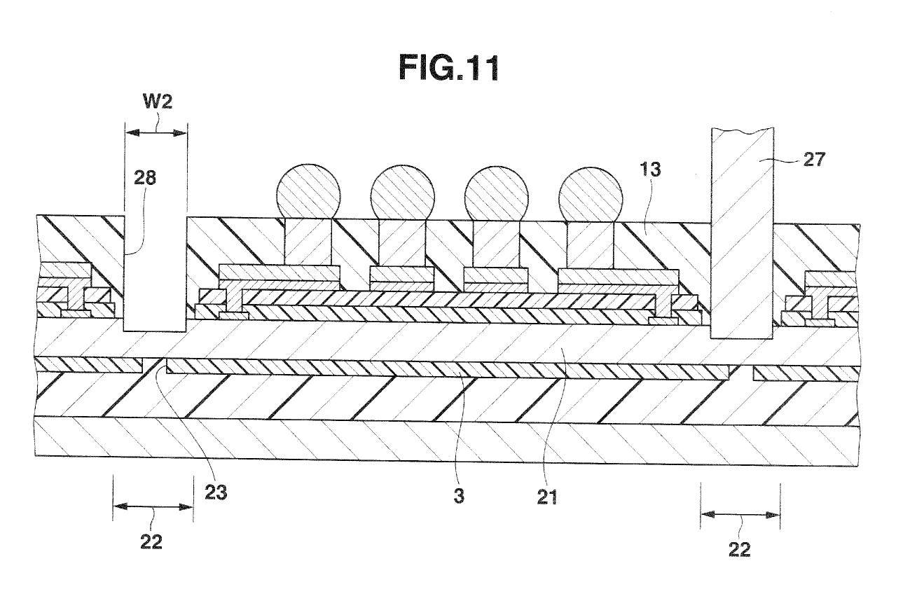

FIG. 11;

FIG. 13 is a sectional view of a semiconductor device according to a second embodiment of this invention;

FIG. 14 is a sectional view of a predetermined step in one example of a method of manufacturing the semiconductor device shown in FIG. 13;

FIG. 15 is a sectional view of a step following FIG. 14;

FIG. 16 is a sectional view of a step following FIG. 15;

FIG. 17 is a sectional view of a step following FIG. 16;

FIG. 18 is a sectional view of a step following FIG. 17;

FIG. 19 is a sectional view of a step following FIG. 18; and

FIG. 20 is a sectional view of a step following FIG. 19.

### DETAILED DESCRIPTION OF THE INVENTION

### First Embodiment

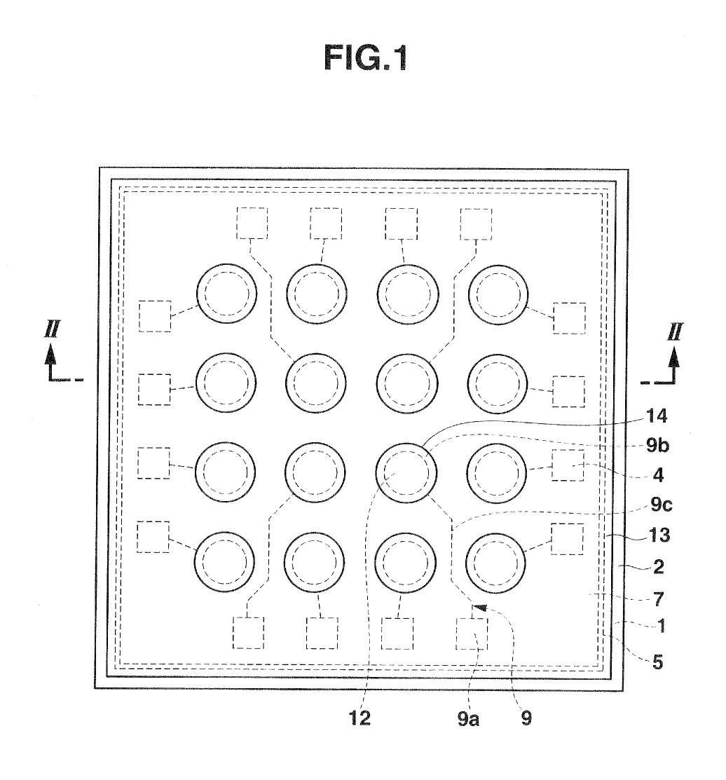

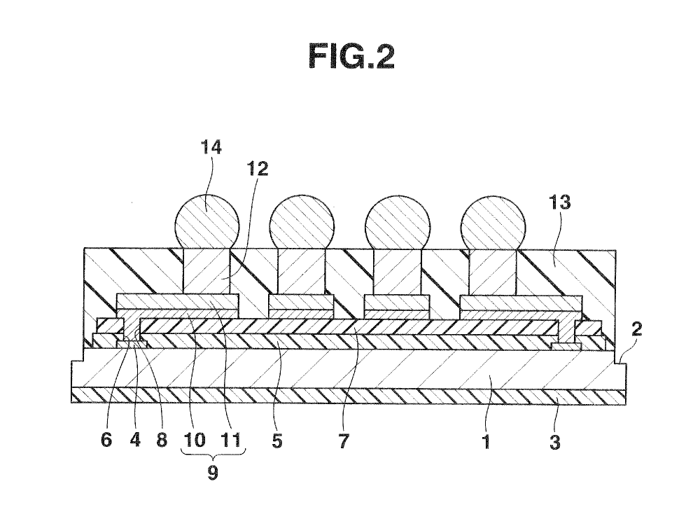

FIG. 1 shows a plan view of a semiconductor device according to a first embodiment of this invention. FIG. 2 shows a sectional view of a part substantially taken along line II-II of FIG. 1. This semiconductor device is generally called a COP, and comprises a silicon substrate (semiconductor substrate) 1. An outer edge 2 substantially rectangular in section is provided on the upper part of the peripheral part of the silicon substrate 1. A rear protective film 3 made of a resin such as an epoxy resin or a polyimide resin is provided on the entire upper surface of the silicon substrate 1.

Although not shown, elements that constitute an integrated circuit having a predetermined function, such as a transistor, a diode, a resistor, and a condenser are formed on the upper surface of the silicon substrate 1. Connection pads 4 made of, for example, an aluminum-based metal and connected to the elements of the integrated circuit are provided in the peripheral part of the upper surface of the silicon substrate 1.

A passivation film (insulating film) 5 made of, for example, silicon oxide or silicon nitride is provided on the upper surface of the silicon substrate 1 except for the peripheral part of the silicon substrate 1 and the centers of the connection pads 4. The center of the connection pad 4 is exposed via an opening 6 provided in the passivation film 5. A protective film (insulating film) 7 made of, for example, a polyimide resin is provided on the upper surface of the passivation film 5. An opening 8 is provided in a part of the protective film 7 corresponding to the opening 6 of the passivation film 5.

Wiring lines 9 are provided on the upper surface of the protective film 7. The wiring line 9 has a two-layer structure composed of a foundation metal layer 10 made of, for example, copper and provided on the upper surface of the protective film 7, and an upper metal layer 11 made of copper and provided on the upper surface of the foundation metal layer 10. One end 9a of the wiring line 9 is connected to the connection pad 4 via the openings 6 and 8 of the passivation film 5 and the protective film 7. The other end of the wiring line 9 is a land 9h. An extension line 9c intervenes between the end 9a and the land 9b. A columnar external connection electrode 12 made of copper is provided on the upper surface of the land 9b of the wiring line 9.

A sealing film 13 made of, for example, an epoxy resin or polyimide resin containing a silica filler is provided on the upper surface of the peripheral part of the silicon substrate 1 except for the outer edge 2 and on the upper surface of the protective film 7 including the wiring line 9 around the external connection electrode 12. In this case, the side surface of the sealing film 13 is flush with the vertical surface of the outer edge 2. Here, the external connection electrode 12 is provided so that its upper surface is flush with or several μm lower than the upper surface of the sealing film 13. A solder bump is provided on the upper surface of the external connection electrode 12.

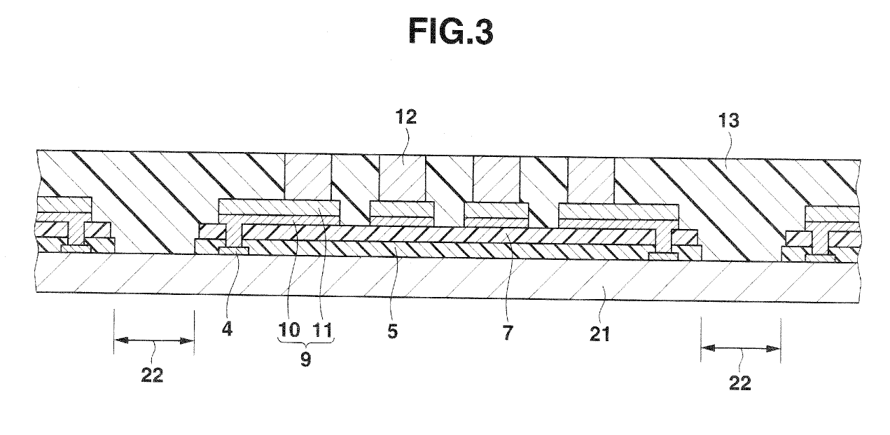

Now, one example of a method of manufacturing this semiconductor device is described. First, as shown in FIG. 3, an assembly is prepared. In this assembly, a connection pad 4, a passivation film 5, a protective film 7, a wiring line 9 having a two-layer structure composed of a foundation metal layer 10 and an upper metal layer 11, an external connection electrode 12, and a sealing film 13 are formed on a silicon substrate in a wafer state (hereinafter referred to as a semiconductor wafer 1). The lower side of the semiconductor wafer 21 has been ground to reduce the thickness of the semiconductor wafer 21.

In this case, the sealing film 13 is made of a resin such as an epoxy resin or polyimide resin containing a silica filler. In FIG. 3, zones indicated by the sign 22 are dicing streets. The parts of the passivation film 5 and the protective film 7 corresponding to the dicing street 22 and both its sides are removed. The sealing film 13 is formed in the removed parts.

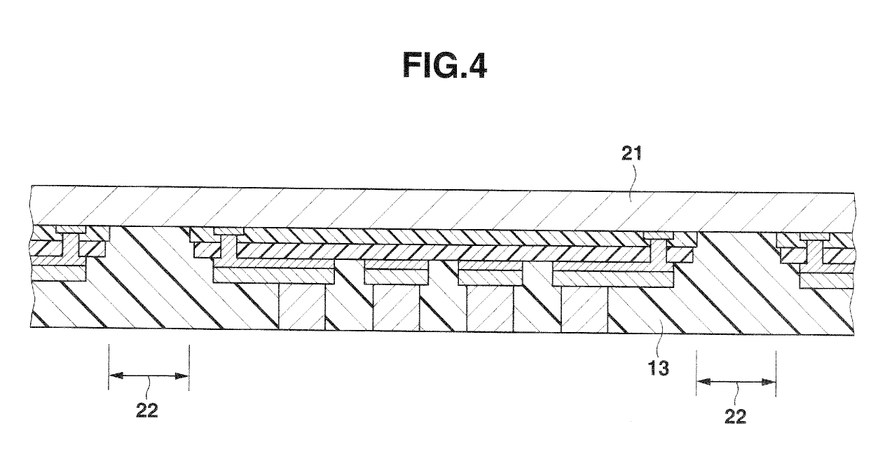

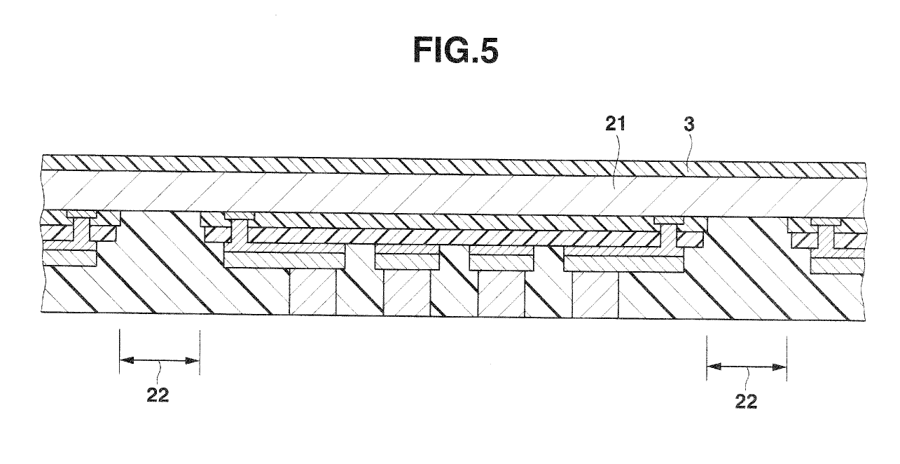

Then, the assembly shown in FIG. 3 is turned upside down to turn up the bottom surface (the surface opposite to the surface in which the sealing film 13 and others are formed) of the semiconductor wafer 21, as shown in FIG. 4. Then, as shown in FIG. 5, a rear protective film 3 made of a resin such as an epoxy resin or a polyimide resin is formed on the upper surface (bottom surface) of the semiconductor wafer 21. The rear protective film 3 may be formed by affixing a resin sheet or by printing or spin coating. When the resin sheet is affixed, the resin sheet having a given thickness (e.g., 20 to 40 μm) can be satisfactorily affixed to the entire upper surface of the semiconductor wafer 21 even if the semiconductor wafer 21 is slightly warped.

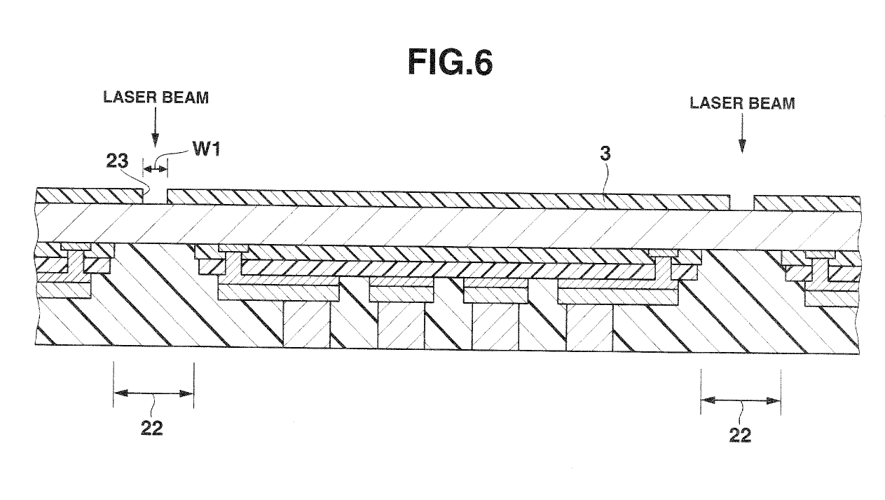

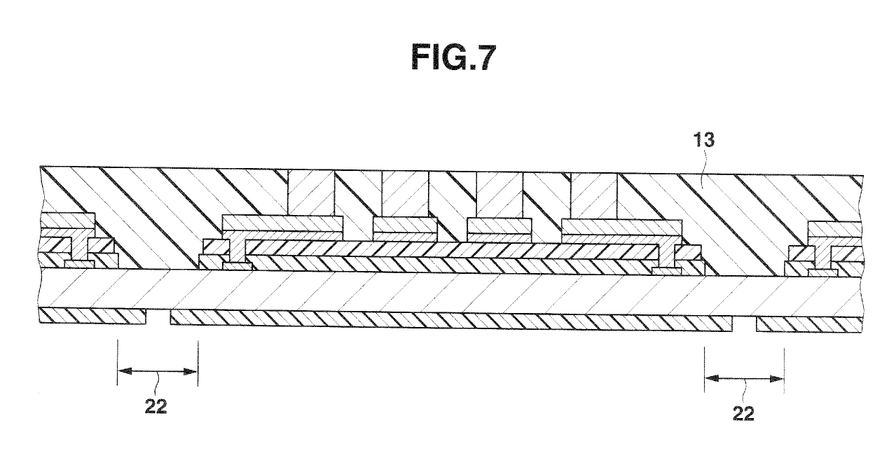

Then, as shown in FIG. 6, a lattice-shaped opening 23 is formed in a part of the rear protective film 3 corresponding to the center of the dicing street 22 by laser processing which applies a laser beam. In this case, if the width of a later-described second silicon cutting blade 29 is, for example, 30 μm, the opening (W1) 23 has a slightly smaller width of, for example, 25 μm. However, the width of the opening is preferably 30 μm which is equal to the width of a later-described second trench (W3) 30. Then, the assembly shown in FIG. 6 is turned upside down to turn up the side in which the sealing film 13 and others are formed, as shown in FIG. 7

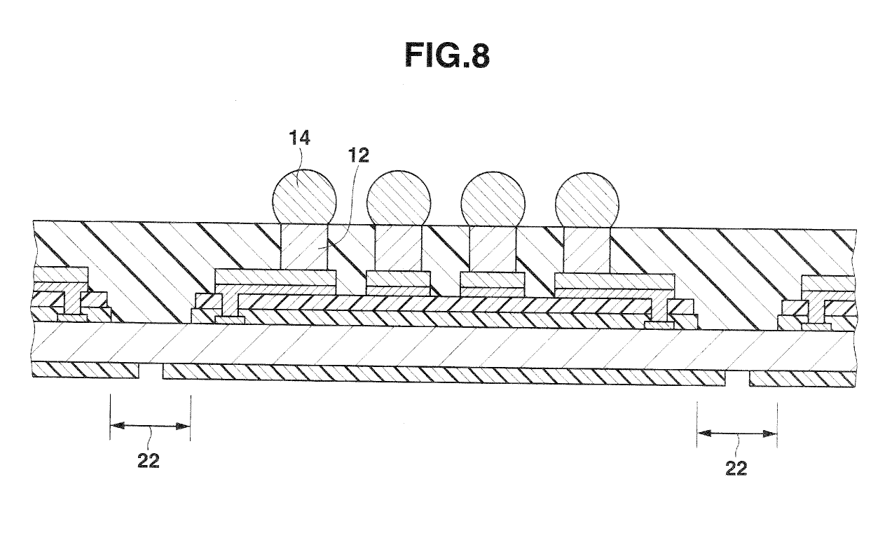

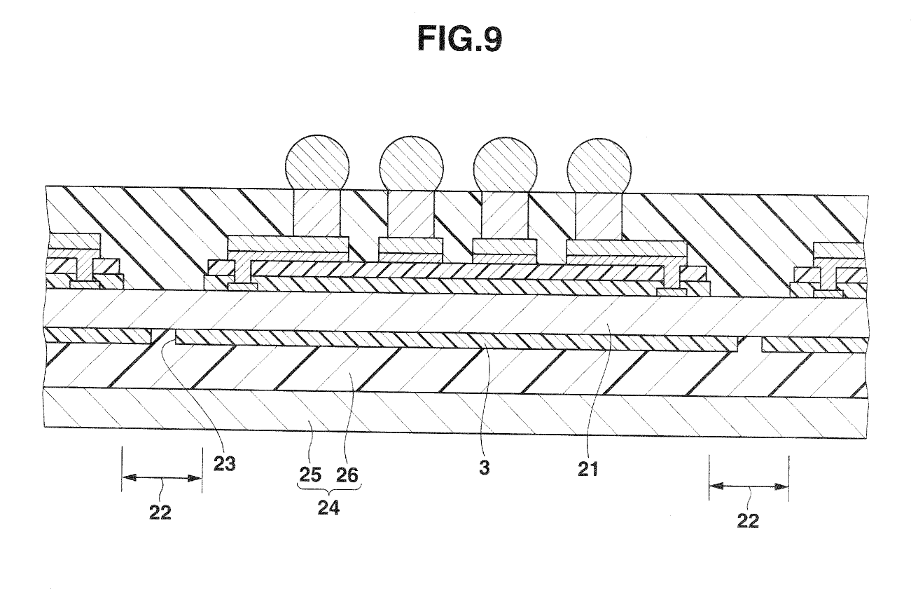

Then, as shown in FIG. 8, a solder bump 14 is formed on the upper surface of the external connection electrode 12. Then, as shown in FIG. 9, the lower surface of the rear protective film 3 is affixed to the upper surface of an adhesive layer 26 of a dicing tape 24 in which the adhesive layer 26 is provided on the upper surface of a film 25. By way of example, the thickness of the film 25 is about 80 μm, and that of the adhesive layer 26 is about 5 to 10 μm.

In this case, if this affixing step is performed in a vacuum chamber (not shown), a part of the adhesive layer 26 of the dicing tape 24 enters the opening 23 of the rear protective film 3 and is bonded to at least part of the lower surface of the semiconductor wafer 21 exposed through the opening 23. This can ensure that the lower surface of the semiconductor wafer 21 exposed through the opening 23 is bonded to the dicing tape 24. As a result, the stability of cutting operation in a later-described dicing process can be higher. The dicing tape 24 is essential to keep semiconductor devices together when the semiconductor wafer 21 is completely divided into semiconductor devices in the end.

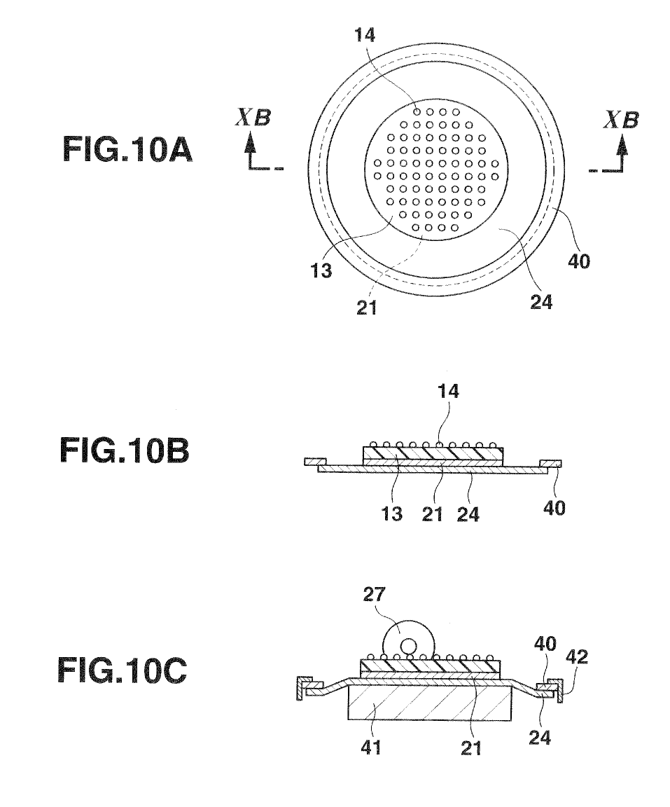

Then, a dicing machine shown in FIG. 10 is prepared. In this case, FIG. 10A shows a plan view of the assembly shown in FIG. 9. FIG. 10B shows a sectional view substantially taken along line B-B of FIG. 10A, FIG. 10C shows a sectional view showing the assembly shown in FIG. 10B that is disposed on a chuck table. The lower surface of the semiconductor wafer 21 is affixed to substantially the center of the upper surface of the circular dicing tape 24 which is larger than the semiconductor wafer 21. Further, a dicing frame 40 is affixed to the lower surface of the outer peripheral part of the dicing tape 24. These are placed on a chuck table 41, and the dicing frame 40 is fixed by a dicing frame jig 42.

Then, the dicing frame jig 42 is lowered so that a later-described first blade 27 does not contact the dicing frame jig 42, and the dicing frame 40 is thereby drawn to a position slightly lower than the lower surface of the semiconductor wafer 21. Further, the semiconductor wafer 21 is vacuum-drawn to the upper surface of the chuck table 41 via the dicing tape 24.

Then, as shown in FIG. 11, the first blade 27 is prepared. The first blade 27 comprises a rosin cutting disk grindstone, and its thickness is less than the width (e.g., 80 μm) of the dicing street 22 and is, for example, about 50 μm. The first blade 27 and an unshown camera are disposed on the semiconductor wafer 21. The first blade 27 is lowered in a rotating state, and the chuck table 41 having the semiconductor wafer 21 thereon is moved, thereby cutting parts of the sealing film 13 and the upper side of the semiconductor wafer 21 corresponding to the dicing street 22 to form a first trench 28. In this case, although the first blade 27 is designed for resin cutting, it is difficult from the viewpoint of processing to only form the first trench (W2) 28 in the sealing film 13 made of an epoxy resin containing a silica filler. Thus, the shallowest possible trench (W2) 28 is formed in the upper side of the semiconductor wafer 21.

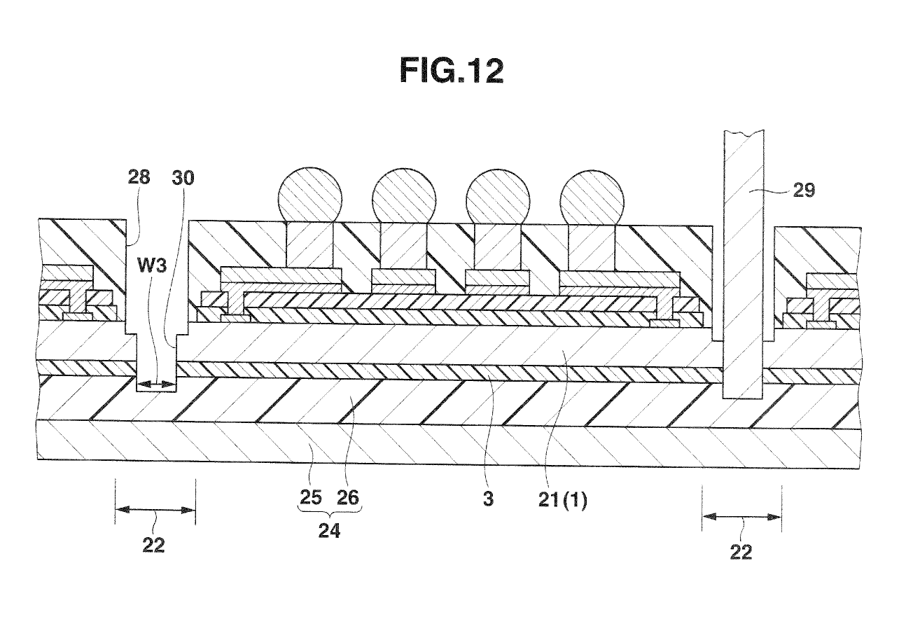

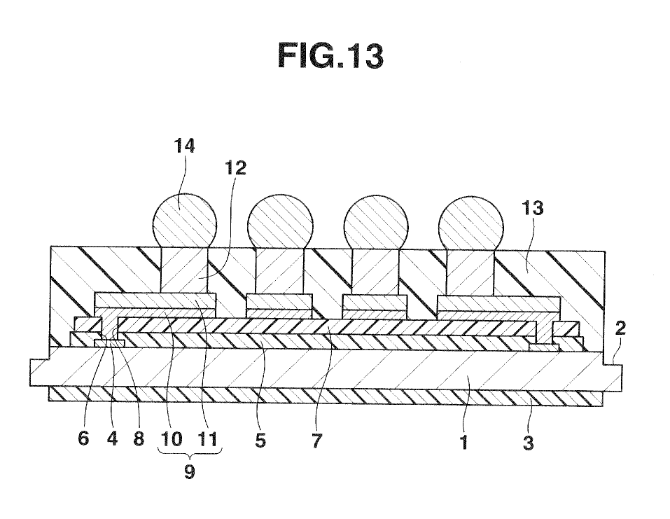

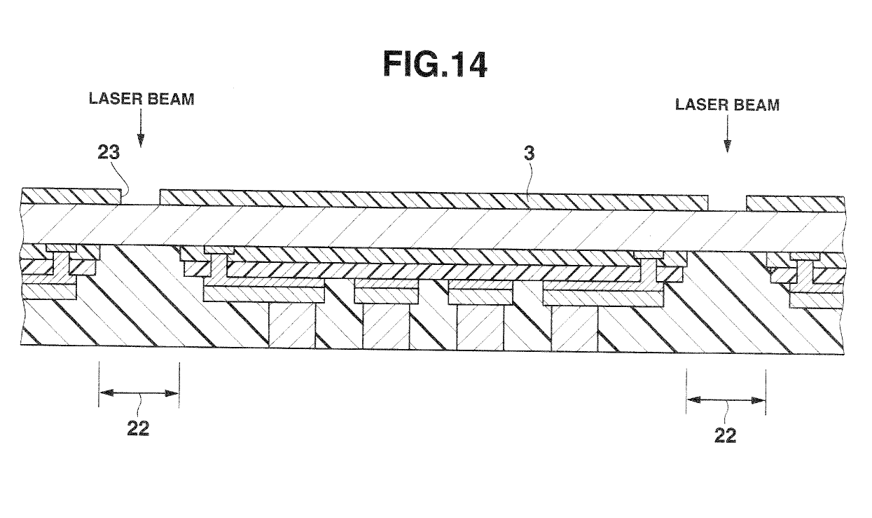

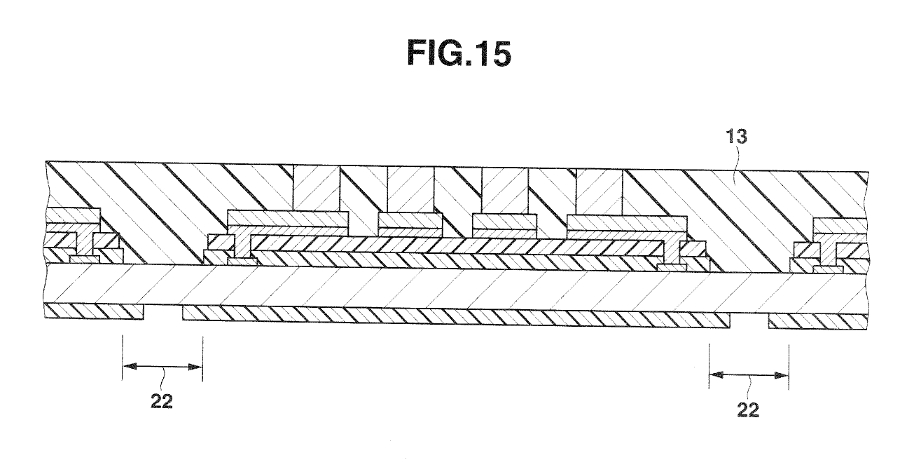

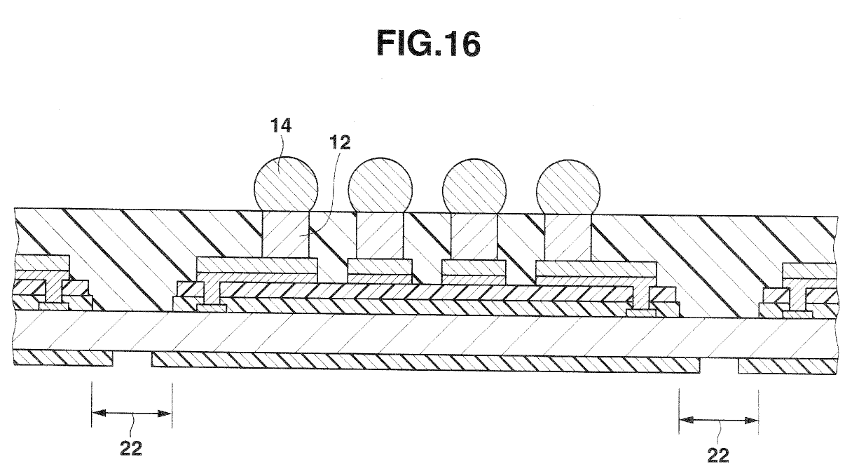

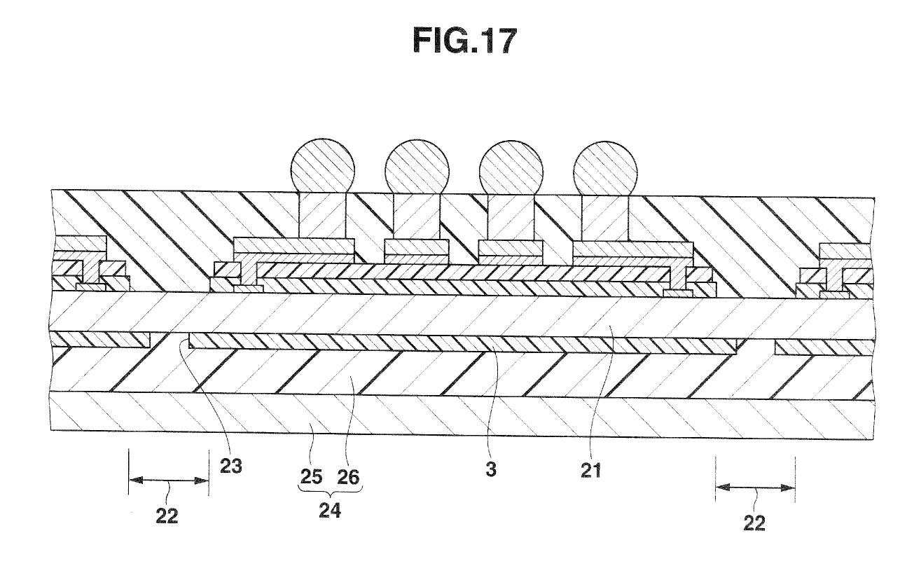

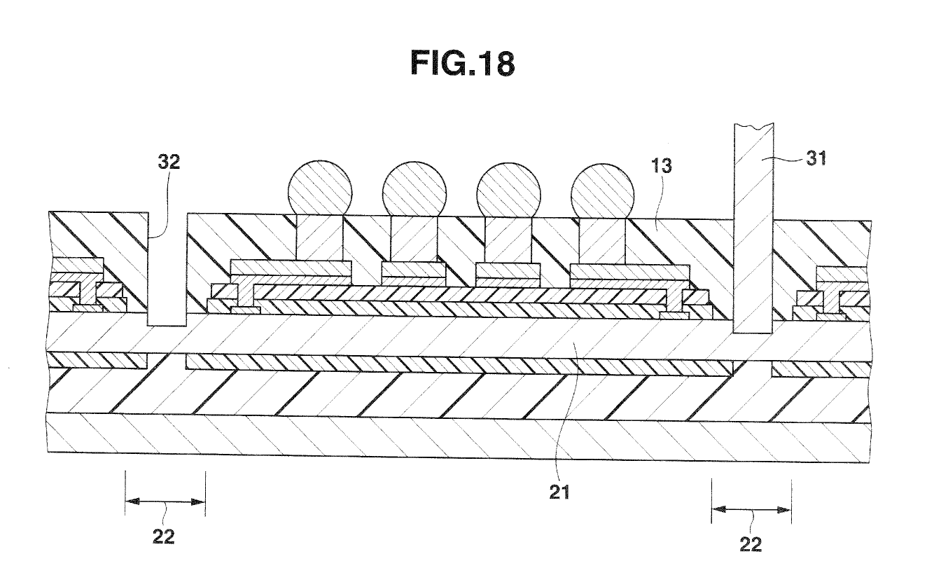

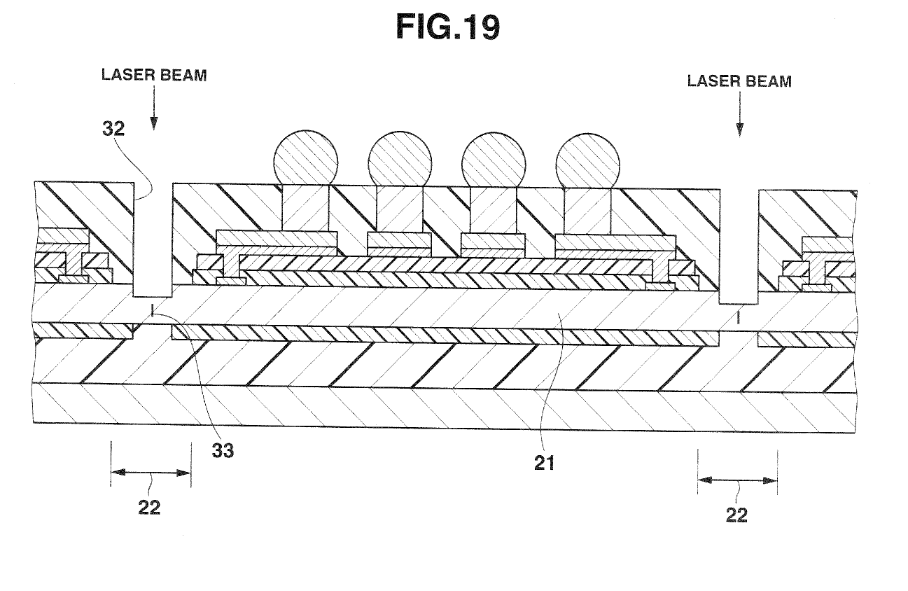

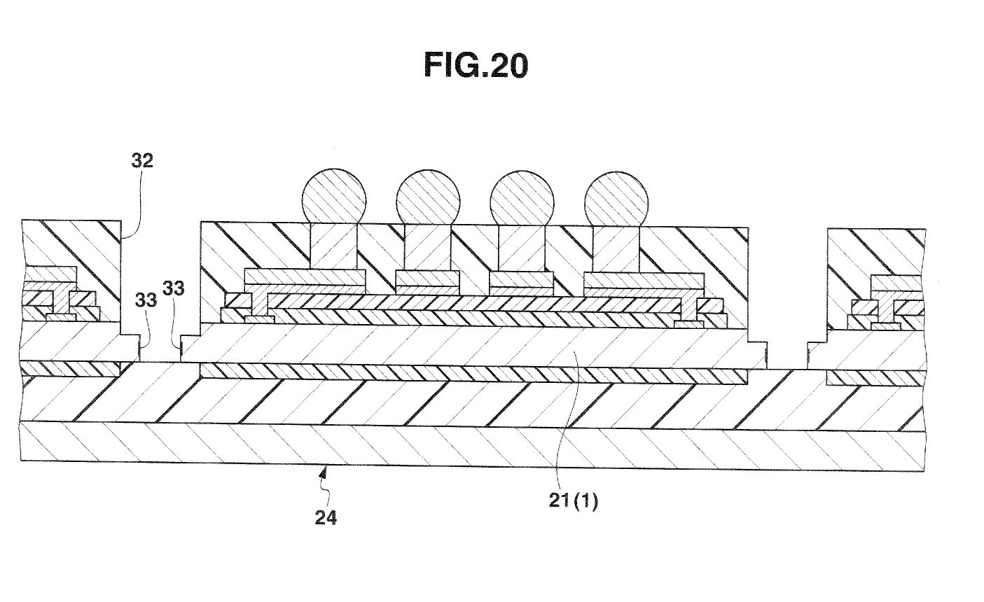

Then, as shown in FIG. 12, the second blade 29 is prepared. The second blade 29 comprises a silicon (semiconductor) cutting disk grindstone, and its thickness is slightly less than the width (e.g., 50 μm) of the first blade and is, for example, about 30 μm. By using the second blade 29, parts of the semiconductor wafer 21, the rear protective film 3, and the upper side of the adhesive layer 26 of the dicing tape 24 corresponding to the dicing street 22 (the center of the first trench 28) are cut to form the second trench (W3) 30, and diced.

In this case, the upper side of the adhesive layer 26 has to be only slightly cut to completely divide into semiconductor devices. Clogging when the upper side of the adhesive layer 26 is cut with the second blade 29 is mentioned. In contrast to the thickness of the film 25 of the dicing tape 24 which is about 80 μm, the thickness of the adhesive layer 26 is as small as about 5 to 10 μm. Therefore, as compared with the cutting of the rear protective film 3 having a thickness of 20 to 40 μm, the cutting of the adhesive layer 26 having a small thickness causes slight clogging but has little influence.

The second blade 29 is designed for silicon cutting. However, the opening 23 is formed in advance in the rear protective film 3 made of, for example, an epoxy resin. Therefore, the rear protective film 3 is less cut with the second blade 29 owing to the opening 23, and the second blade 29 is at a much lower risk of being clogged with the resin, thereby making it possible to inhibit the chipping of the cut surface of the semiconductor wafer 21. When the entire lower surface of the semiconductor wafer 21 is covered with the rear protective film 3, the chipping of the cut surface of the semiconductor water 21 can be further prevented. It is, however, preferable that the width of the opening (W1) 23 of the rear protective film 3 be equal to the width of the second blade 29 for cutting the semiconductor wafer 21 to form the second trench (W3) 30 for dicing. This makes it possible to reduce the frequency of precutting with the second blade 29 and prolong the life of the second blade 29.

On the other hand, in the condition shown in FIG. 12, the parts of the semiconductor wafer 21 and the rear protective film 3 corresponding to the dicing street 22 are completely cut into the silicon substrates 1 and the rear protective films 3. If the divided silicon substrates 1 and others are then picked up from the dicing tape 24, the semiconductor devices shown in FIG. 2 can be obtained.

### Second Embodiment

FIG. 13 shows a sectional view of a semiconductor device according to a second embodiment of this invention. This semiconductor device is greatly different from the semiconductor device shown in FIG. 2 in that a rear protective film 3 is provided on the lower surface of a silicon substrate 1 except for its outer edge.

Now, one example of a method of manufacturing this semiconductor device is described. First, after the step shown in FIG. 5, a lattice-shaped opening 23 is formed in a part of the rear protective film 3 corresponding to the center of the dicing street 22 by laser processing which applies a laser beam, as shown in FIG. 14. In this case, if the width of a silicon cutting dicing blade is, for example, 30 μm, the opening 23 also has an width of 30 μm. Then, the assembly shown in FIG. 14 is turned upside down to turn up the side in which a sealing film 13 and others are formed, as shown in FIG. 15.

Then, as shown in FIG. 16, a solder bump 14 is formed on the upper surface of an external connection electrode 12. Then, as shown in FIG. 17, the lower surface of the rear protective film 3 is affixed to the upper surface of an adhesive layer 26 of a dicing tape 24. In this case as well, if this affixing step is performed in a vacuum chamber (not shown), a part of the adhesive layer 26 of the dicing tape 24 enters the opening 23 of the rear protective film 3 and is bonded to at least part of the lower surface of the semiconductor wafer 21 exposed through the opening 23. As a result, the stability of cutting operation in a later-described dicing process can be higher.

Then, as shown in FIG. 18, a blade (first blade) 31 is prepared. The blade 31 comprises a resin cutting disk grindstone, and its thickness is less than the width (e.g., 80 μm) of the dicing street 22 and is, for example, about 30 μm. By using the blade 31, parts of the sealing film 13 and the upper side of the semiconductor wafer 21 corresponding to the dicing street 22 are cut to form a trench 32. In this case as well, although the blade 31 is designed for resin cutting, it is difficult from the viewpoint of processing to only form the trench 32 in the sealing film 13 made of an epoxy resin containing a silica filler. Thus, the shallowest possible trench 32 is formed in the upper side of the semiconductor wafer 21.

Then, as shown in FIG. 19, a part of the semiconductor wafer 21 exposed through the trench 32 corresponding to the center of the dicing street 22 in its width direction is subjected to stealth dicing. That is, by using an objective lens optical system (not shown), a laser beam having a wavelength ranging from about 1000 nm to a long-wave near-infrared region which is permeable to the semiconductor wafer 21 is focused on and applied to an inner part of the semiconductor wafer 21 corresponding to the center of the dicing street 22 in its width direction. As a result, a stealth dicing layer (vertical crack) 33 having a width of several μm is formed in the center of the semiconductor wafer 21 in its width direction corresponding to the center of the dicing street 22 in its width direction.

Then, as shown in FIG. 20, the dicing tape 24 is pulled and extended in its peripheral direction, such that the trench 32 is increased in width accordingly, and the semiconductor wafer 21 is divided at the stealth dicing layer 33 into silicon substrates 1. In this way, the semiconductor wafer 21 is internally divided, in marked contrast to laser dicing for externally cutting the semiconductor wafer. The laser dicing mostly uses laser light having a wavelength that is highly absorbed by the material of an object to be diced. Therefore, this laser light generates heat at the time of laser processing, and affects device features. In this respect, the stealth dicing permits the laser light to be guided to near the focus within the semiconductor wafer, and therefore causes no damage to the surface layer of the semiconductor wafer.

In this case, the stealth dicing is used, and no blade is used, so that the disadvantage associated with the use of the blade can be eliminated. The stealth dicing provides a low running cost and still provides a high dicing speed, and neither chips the semiconductor wafer nor produces dust. If the divided silicon substrates 1 and others are then picked up from the dicing tape 24, the semiconductor devices shown in FIG. 13 can be obtained.

### Other Embodiments

The solder bump 14 is not exclusively formed at the time described in the first and second embodiments. That is, as shown in FIG. 5, the solder bump 14 may be formed on the external connection electrode 12 after the rear protective film 3 is formed on the upper surface (bottom surface) of the semiconductor wafer 21. However, in this case, the adhesive layer 26 of the dicing tape 24 needs to have a thickness enough to cover the solder bump 14. Moreover, the solder bump 14 may be directly formed on the upper metal layer 11 without forming the external connection electrode 12.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate;
a sealing film provided on one side of the semiconductor substrate; and
a rear protective film provided on the other side of the semiconductor substrate except for at least the semiconductor substrate's outer edge.

2. The semiconductor device according to claim 1, wherein
an insulating film is provided on one surface of the semiconductor substrate,
a wiring line is provided on the insulating film,
an external connection electrode is provided on a land of the wiring line, and
the sealing film is provided around the external connection electrode.

3. The semiconductor device according to claim 1, wherein the side surface of the sealing film is flush with a vertical surface of the outer edge.

4. The semiconductor device according to claim 2, wherein a solder bump is provided on the external connection electrode.

5. A semiconductor device manufacturing method comprising:
forming a sealing film on one side of a semiconductor wafer and forming a rear protective film on the other side thereof;
forming an opening in a part of the rear protective film corresponding to a dicing street;
forming, with a first blade, a trench in at least a part of the sealing film corresponding to the dicing street; and
dicing, with a second blade, at least the semiconductor wafer in a part corresponding to the dicing street.

6. The semiconductor device manufacturing method according to claim 5, wherein a wiring line and an external connection electrode provided on a land of the wiring line are provided on one side of the semiconductor wafer.

7. The semiconductor device manufacturing method according to claim 5, wherein the part of the rear protective film corresponding to the dicing street is diced with the second blade.

8. The semiconductor device manufacturing method according to claim 5, wherein the opening is formed in the rear protective film by laser processing which applies a laser beam.

9. The semiconductor device manufacturing method according to claim 5, wherein the rear protective film is formed by affixing a resin sheet to the lower surface of the semiconductor wafer.

10. The semiconductor device manufacturing method according to claim 5, wherein the lower surface of the rear protective film is affixed to the upper surface of a dicing tape before the semiconductor wafer is divided into semiconductor substrates.

11. The semiconductor device manufacturing method according to claim 5, wherein the first blade is a resin cutting blade, and the second blade is a semiconductor cutting blade.

12. The semiconductor device manufacturing method according to claim 7, wherein a solder bump is formed on an external connection electrode after the opening is formed in the rear protective film.

13. The semiconductor device manufacturing method according to claim 7, wherein a solder bump is formed on an external connection electrode after the rear protective film is formed on the lower surface of the semiconductor wafer.

14. A semiconductor device manufacturing method comprising:
forming a sealing film on one side of a semiconductor wafer and forming a rear protective film on the other side thereof;
forming an opening in a part of the rear protective film corresponding to a dicing street;
forming, with a first blade, a trench in at least a part of the sealing film corresponding to the dicing street; and
dividing, by stealth dicing, at least the semiconductor wafer in a part corresponding to the dicing street.

15. The semiconductor device manufacturing method according to claim 14, wherein a wiring line and an external connection electrode provided on a land of the wiring line are provided on one side of the semiconductor wafer.

16. The semiconductor device manufacturing method according to claim 14, wherein the stealth dicing comprises affixing the lower surface of the rear protective film to the upper surface of a dicing tape, and forming a stealth dicing layer in a part of the semiconductor wafer corresponding to the center of the trench in its width direction, and
pulling and extending the dicing tape in its peripheral direction, and thereby dividing the semiconductor wafer at the stealth dicing layer into semiconductor substrates.

17. The semiconductor device manufacturing method according to claim 14, wherein the opening is formed in the rear protective film by laser processing which applies a laser beam.

18. The semiconductor device manufacturing method according to claim 14, wherein the rear protective film is formed by affixing a resin sheet to the lower surface of the semiconductor wafer.

19. The semiconductor device manufacturing method according to claim 14, wherein the lower surface of the rear protective film is affixed to the upper surface of a dicing tape before the semiconductor wafer is divided into semiconductor substrates.

20. The semiconductor device manufacturing method according to claim 14, wherein the first blade is a resin cutting blade.

21. The semiconductor device manufacturing method according to claim 15, wherein a solder bump is formed on the external connection electrode after the opening is formed in the rear protective film.

22. The semiconductor device manufacturing method according to claim 15, wherein a solder bump is formed on the external connection electrode after the rear protective film is formed on the lower surface of the semiconductor wafer.
